(19) United States
(12) Patent Application Publication
(10) Pub. No.: US 2026/0026395 A1
(43) Pub. Date: Jan. 22, 2026

(54) SEMICONDUCTOR WAFER, SEMICONDUCTOR DEVICE, POWER CONVERSION APPARATUS, AND COOLING SYSTEM

(71) Applicant: Mitsubishi Electric Corporation, Tokyo (JP)

(72) Inventors: Yasuo ATA, Tokyo (JP); Masakazu TANI, Tokyo (JP); Shigeo TOI, Tokyo (JP)

(73) Assignee: Mitsubishi Electric Corporation, Tokyo (JP)

(21) Appl. No.: 18/997,386

(22) PCT Filed: Oct. 11, 2022
(86) PCT No.: PCT/JP2022/037823

§ 371 Date: Jan. 21, 2025

(51) Int. Cl. H01L 23/31; H01L 21/78; H01L 23/00; H05K 7/20

(52) U.S. Cl. CPC H01L 23/3192; H01L 21/78; H01L 23/562; H05K 7/2029

(57) ABSTRACT

A semiconductor wafer includes a semiconductor substrate on which an interlayer insulating film and a surface protective film are laminated on an upper surface. A plurality of semiconductor elements to be divided into small pieces by dicing along an opening formed in the surface protective film are formed on the semiconductor substrate. An end of the interlayer insulating film is retracted more than an end of the surface protective film with respect to an end of the semiconductor substrate to be formed by the dicing, and a shape of the end of the interlayer insulating film is set such that, in each of the semiconductor elements after the dicing, a distance Lx from a corner of the semiconductor substrate to be formed by the dicing to the end of the interlayer insulating film and a thickness d of the semiconductor substrate satisfy a certain condition.

### TECHNICAL FIELD

The present disclosure relates to a semiconductor wafer, a semiconductor device, a power conversion apparatus, and a cooling system.

### BACKGROUND ART

Patent Document 1 discloses a structure in which an interlayer insulating film is formed on a semiconductor wafer and a surface protective film is formed so as to overlap and cover the interlayer film. For example, in this structure, a length from an end of a semiconductor element to the surface protective film excluding a width 80 μm of an opening of the surface protective film and a gap 50 μm of a scribe line is 30 μm/2=15 μm, and a thickness of a product is 180 μm.

### PRIOR ART DOCUMENT

### Patent Document

### Patent Document 1: Japanese Patent Application Laid-Open No. 2016-225511

### SUMMARY

### Problem to be Solved by the Invention

In a technique described in Patent Document 1, since the length from the end of the semiconductor element to the surface protective film is as short as about 15 μm, there is a problem that external stress due to thermal shrinkage stress is applied to the end of the semiconductor element, so that a crack is likely to occur from the surface protective film to the lower side of the interlayer insulating film. When the crack extends to the lower side of the interlayer insulating film, a withstand voltage of the semiconductor element decreases, and thus, a length of the crack is important. The external stress due to the thermal shrinkage stress increases at four corners in the ends of the semiconductor element, so that the withstand voltage of the semiconductor element is likely to decreases when the crack extends to the lower side of the interlayer insulating film.

In addition, such a semiconductor element is mounted on a power module. For example, a power module of a power conversion apparatus mounted on a vehicle has a wider range of operating temperatures (for example, in the range of −40° C. or more and 150° C. or less) than a power module used indoors, and is used in a severe heat cycle environment. In addition, in a low temperature environment, torque is applied to a motor at the time of starting, so that the temperature of the entire drive equipment rapidly rises. For this reason, there is a problem that peeling between a sealing resin and the semiconductor element in the power module occurs so that dielectric breakdown of the semiconductor element occurs.

Therefore, an object of the present disclosure is to provide a technique capable of suppressing a crack from extending to the lower side of an interlayer insulating film when external stress due to thermal shrinkage stress is applied to a corner of a semiconductor element.

### Means to Solve the Problem

A semiconductor wafer according to the present disclosure is a semiconductor wafer including a semiconductor substrate in which an interlayer insulating film and a surface protective film covering the interlayer insulating film are laminated on an upper surface, wherein a plurality of semiconductor elements to be divided into small pieces by dicing along an opening formed in the surface protective film are formed on the semiconductor substrate, an end of the interlayer insulating film is retracted more than an end of the surface protective film with respect to an end of the semiconductor substrate to be formed by the dicing, and a shape of the end of the interlayer insulating film is set in such a manner that, in each of the semiconductor elements after the dicing, a distance Lx from a corner of the semiconductor substrate to be formed by the dicing to the end of the interlayer insulating film and a thickness d of the semiconductor substrate satisfy a relationship of Formula 1.

### Effects of the Invention

According to the present disclosure, since the distance Lx from the corner of the semiconductor substrate to the end of the interlayer insulating film is long, so that it is possible to suppress the crack from extending to the lower side of the interlayer insulating film when the external stress due to the thermal shrinkage stress is applied to the corner of the semiconductor element.

Objects, features, aspects, and advantages of the present disclosure will become more apparent from the following detailed description and the due to drawings.

### BRIEF DESCRIPTION OF DRAWINGS

FIG. 1 is a top view of a semiconductor wafer according to a first embodiment.

FIG. 2 is a top view and a cross-sectional view of a corner of a semiconductor element to be formed by dicing in the semiconductor wafer according to the first embodiment.

FIG. 3 is a graph showing a relationship between a length of a crack from the corner of the semiconductor element and a thickness of the semiconductor element when external stress due to thermal shrinkage stress is applied to the corner of the semiconductor element.

FIG. 4 is a cross-sectional view of a corner of a semiconductor element to be formed by dicing in a semiconductor wafer according to a third embodiment.

FIG. 5 is a cross-sectional view of a corner of a semiconductor element to be formed by dicing in a semiconductor wafer according to a fourth embodiment.

FIG. 6 is a block diagram illustrating a configuration of a power conversion system to which a power conversion apparatus according to a fifth embodiment is applied.

FIG. 7 is a block diagram illustrating a configuration of a cooling system according to a sixth embodiment.

### DESCRIPTION OF EMBODIMENTS

### First Embodiment

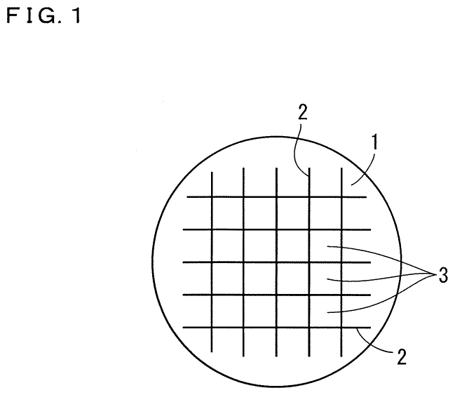

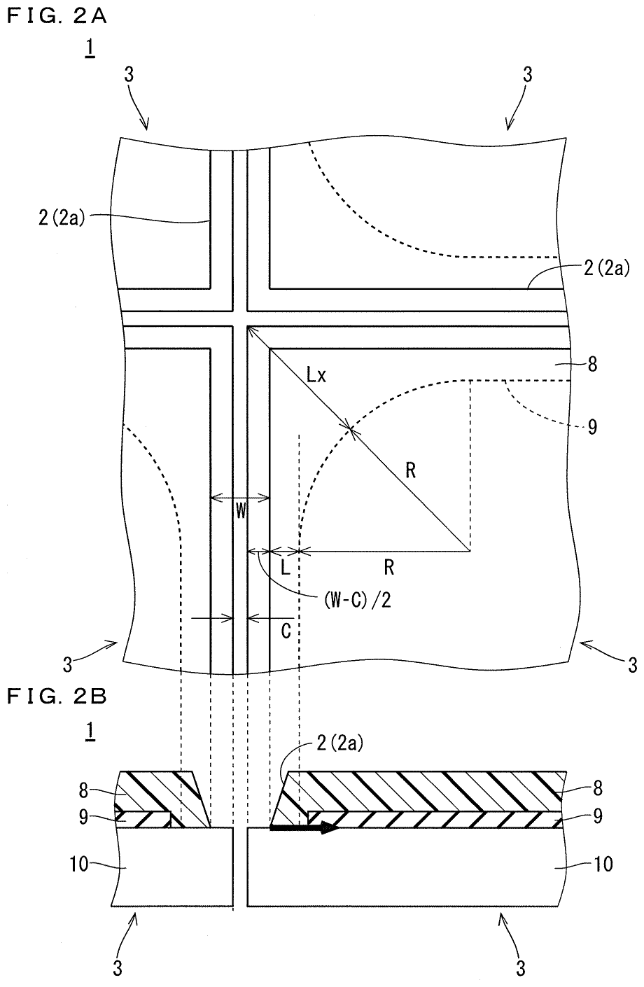

A first embodiment will be described below with reference to the drawings. FIG. 1 is a top view of a semiconductor wafer 1 according to the first embodiment. FIG. 2 (a) is a top view of corners of semiconductor elements 3 to be formed by dicing in the semiconductor wafer 1 according to the first embodiment. FIG. 2 (b) is a cross-sectional view of the corners of the semiconductor elements 3 to be formed by the dicing in the semiconductor wafer 1 according to the first embodiment.

As illustrated in FIG. 1, the semiconductor wafer 1 is formed in a disk shape. In a region of the semiconductor wafer 1 excluding a peripheral edge portion, a plurality of the semiconductor elements 3 to be divided into small pieces by the dicing are formed. Further, in the region of the semiconductor wafer 1 excluding the peripheral edge portion, a plurality of dicing lines 2 for division into the plurality of semiconductor elements 3 are formed in directions intersecting each other. Each of the semiconductor elements 3 obtained from the semiconductor wafer 1 is mounted on a semiconductor device (power module) through known processing.

As illustrated in FIGS. 2 (a) and 2 (b), the semiconductor wafer 1 includes a semiconductor substrate 10, an interlayer insulating film 9, and a surface protective film 8.

The semiconductor substrate 10 is formed in a disk shape. A base material of the semiconductor substrate 10 is SiC. Note that the base material of the semiconductor substrate 10 may be Si or GaN. The interlayer insulating film 9 and the surface protective film 8 are laminated on an upper surface of the semiconductor substrate 10.

The interlayer insulating film 9 is, for example, a TEOS film, and covers the upper surface of the semiconductor substrate 10. Specifically, the interlayer insulating film 9 is provided in a region excluding a peripheral edge portion of the semiconductor element 3 to be formed by the dicing, and portions of the interlayer insulating film 9 corresponding to four corners of the semiconductor element 3 are formed in a curved shape with rounded corners in the top view.

The surface protective film 8 is, for example, polyimide, and is provided so as to cover the interlayer insulating film 9 from above. The dicing line 2 is formed by an opening 2a that is open upward. An end of the interlayer insulating film 9 is retracted more than an end of the surface protective film 8 with respect to an end of the semiconductor substrate 10 to be formed by the dicing. That is, the surface protective film 8 covers the entire interlayer insulating film 9. Note that an arrow in FIG. 2 (b) indicates a direction in which a crack extends.

In the first embodiment, in order to prevent the crack from extending to the lower side of the interlayer insulating film 9 when external stress due to thermal shrinkage stress is applied to the corner of the semiconductor element 3, a shape of the end of the interlayer insulating film 9 is set such that a distance Lx from a corner of the semiconductor substrate 10 to be formed by the dicing to the end of the interlayer insulating film 9 and a thickness d of the semiconductor substrate 10 satisfy a relationship of Formula 1 in each of the semiconductor elements 3 after the dicing.

$$Lx > 10 \times d - 717 μ m \qquad [ Formula 1 ]$$

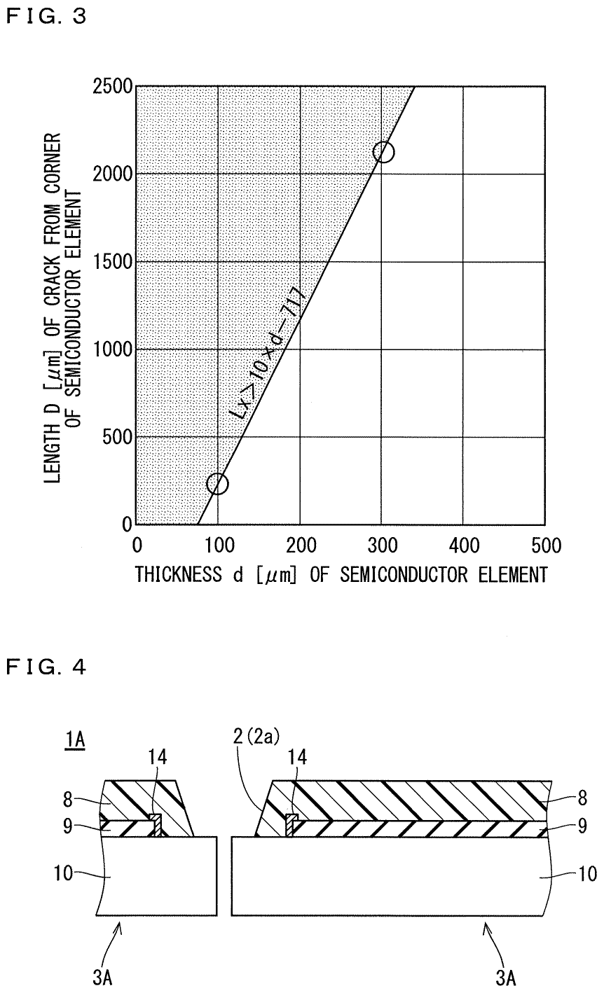

Hereinafter, a reason why the effect of suppressing the crack from extending to the lower side of the interlayer insulating film 9 when the external stress due to the thermal shrinkage stress is applied to the corner of the semiconductor element 3 can be obtained by setting the shape of the end of the interlayer insulating film 9 to satisfy the relationship of Formula 1 will be described. FIG. 3 is a graph showing a relationship between a length D of the crack from the corner of the semiconductor element 3 and the thickness d of the semiconductor element 3 when the external stress due to the thermal shrinkage stress is applied to the corner of the semiconductor element 3.

As the thickness d of the semiconductor element 3 increases, the thermal shrinkage stress on the semiconductor element 3 increases, so that the external stress is likely to be applied. A point at which the highest external stress is applied is the corner of the semiconductor element 3, and the crack is likely to occur at the point. Therefore, as the thickness d of the semiconductor substrate 10 (hereinafter, also referred to as the “thickness d”) increases, it is necessary to take measures against the occurrence of the crack. Specifically, even if the crack occurs, the crack is less likely to extend to the end of the interlayer insulating film 9 by increasing a length of the distance Lx from the corner of the semiconductor substrate 10 to the end of the interlayer insulating film 9 (hereinafter, also referred to as the “distance Lx”), and thus, the distance Lx needs to be increased when the thickness d increases. The inventor of the present application conducted an experiment using the semiconductor elements 3 having different thicknesses d, and found that a relationship between the distance Lx and the thickness d is represented by a linear relational expression of Formula 1.

FIG. 3 shows the relationship between the length D of the crack from the corner of the semiconductor element 3 and the thickness d using data obtained by evaluating the semiconductor elements 3 having different thicknesses d. As shown in FIG. 3, in the semiconductor element 3 having d=100 μm and the semiconductor element 3 having d=300 μm, the length D of the crack is longer when d=300 μm, and the relationship thereof is expressed by a linear relational expression of Formula 1. Since the crack does not extend to the end of the interlayer insulating film 9 when the distance Lx is longer than the length D of the crack, the above effect can be obtained by satisfying Formula 1.

Here, the thickness d is, for example, about 100 μm, and the distance Lx is, for example, about 300 μm. The interlayer insulating film 9 is completely covered up to the end thereof by the surface protective film 8, and a width of the interlayer insulating film 9 covered by the surface protective film 8 is, for example, about ⅓ of the distance Lx.

As described above, the semiconductor wafer 1 according to the first embodiment includes the semiconductor substrate 10 in which the interlayer insulating film 9 and the surface protective film 8 covering the interlayer insulating film 9 are laminated on the upper surface, and the plurality of semiconductor elements 3 to be divided into small pieces by the dicing along the opening 2a formed in the surface protective film 8 are formed on the semiconductor substrate 10. The end of the interlayer insulating film 9 is retracted more than the end of the surface protective film 8 with respect to the end of the semiconductor substrate 10 to be formed by the dicing, and the shape of the end of the interlayer insulating film 9 is set such that, in each of the semiconductor elements 3 after the dicing, the distance Lx from the corner of the semiconductor substrate 10 to be formed by the dicing to the end of the interlayer insulating film 9 and the thickness d of the semiconductor substrate 10 satisfy the relationship of Formula 1.

Therefore, since the distance Lx from the corner of the semiconductor substrate 10 to the end of the interlayer insulating film 9 becomes long, when the external stress due to the thermal shrinkage stress is applied to the corner of the semiconductor element 3, it is possible to suppress the crack from extending to the lower side of the interlayer insulating film 9. As described above, the durability of the semiconductor device including the semiconductor element 3 obtained from the semiconductor wafer 1 is improved.

### Second Embodiment

Next, the semiconductor wafer 1 according to a second embodiment will be described. Note that, in the second embodiment, the same components as those described in the first embodiment are denoted by the same reference signs, and description thereof is omitted.

The distance Lx is affected by a finish of the dicing line 2, which is a cut state of a width W of the dicing line and a kerf width C. Therefore, it is necessary to consider the finish of the dicing line 2 in order to set a shape of an end of the interlayer insulating film 9 with high accuracy. Therefore, in the second embodiment, the shape of the end of the interlayer insulating film 9 is set so as to satisfy the following Formula 2 in addition to Formula 1 in order to consider the finish of the dicing line 2.

The shape of the end of the interlayer insulating film 9 is set such that the width W of the dicing line 2, the kerf width C, which is a width of the dicing line 2 removed by dicing, a width L from an end of the surface protective film 8 to the end of the interlayer insulating film 9 in each of the semiconductor elements 3, a curvature R of the interlayer insulating film 9 at a corner of the semiconductor element 3, and the distance Lx satisfy the relationship of Formula 2.

$$Lx = \sqrt{2} \times ( ( W - C ) / 2 + L ) + ( \sqrt{2} - 1 ) \times R \qquad [ Formula 2 ]$$

A method of deriving Formula 2 will be described with reference to FIG. 2. As illustrated in FIG. 2, a square in which a length of a side is R+L+ (W−C)/2) has a diagonal length of Lx+R. The diagonal length of the square is expressed by an expression of Lx+R=R+L+ (W−C)/2)×√2. Formula 2 is obtained from this expression.

Here, the width W of the dicing line 2 is, for example, about 150 μm, and the kerf width C is, for example, about 50 μm. In addition, the width L from the end of the surface protective film 8 to the end of the interlayer insulating film 9 in each of the semiconductor elements 3 is, for example, about 80 μm, and the curvature R of the interlayer insulating film 9 is, for example, about 500 μm. As a result, the distance Lx is, for example, 391 μm. Note that setting the shape of the end of the interlayer insulating film 9 so as to satisfy the relationship of Formula 2 in addition to the relationship of Formula 1 can also be adopted in the following third and fourth embodiments.

As described above, since the shape of the end of the interlayer insulating film 9 is set so as to satisfy the relationship of Formula 2 in addition to the relationship of Formula 1 in the semiconductor wafer 1 according to the second embodiment, the shape of the end of the interlayer insulating film 9 can be set with high accuracy by considering the finish of the dicing line 2. As a result, it is possible to further improve the effect of suppressing a crack from extending to the lower side of the interlayer insulating film 9 when external stress due to thermal shrinkage stress is applied to the corner of the semiconductor element 3.

### Third Embodiment

Next, a semiconductor wafer 1A according to the third embodiment will be described. FIG. 4 is a cross-sectional view of corners of semiconductor elements 3A to be formed by dicing in the semiconductor wafer 1A according to the third embodiment. Note that, in the third embodiment, the same components as those described in the first and second embodiments are denoted by the same reference signs, and description thereof is omitted.

As illustrated in FIG. 4, in the third embodiment, an AlSi film 14 is disposed on an outer peripheral surface of an end of the interlayer insulating film 9 so as to cover the end of the interlayer insulating film 9 in each of the semiconductor elements 3A. The AlSi film 14 is disposed so as to cover the entire outer peripheral surface of the end of the interlayer insulating film 9, and functions as a buffer against a crack extending from a corner of the semiconductor element 3A. Note that the AlSi film 14 may be disposed up to an upper surface of the interlayer insulating film 9 from the end of the interlayer insulating film 9 instead of being disposed only on the outer peripheral surface of the end of the interlayer insulating film 9.

As described above, in the semiconductor wafer 1A according to the third embodiment, the AlSi film 14 is disposed on the outer peripheral surface of the end of the interlayer insulating film 9 so as to cover the end of the interlayer insulating film 9 in each of the semiconductor elements 3A. Therefore, the AlSi film 14 functions as the buffer for the crack extending from the corner of the semiconductor element 3A, so that it is possible to further improve the effect of suppressing the crack from extending to the lower side of the interlayer insulating film 9 when external stress due to thermal shrinkage stress is applied to the corner of the semiconductor element 3.

### Fourth Embodiment

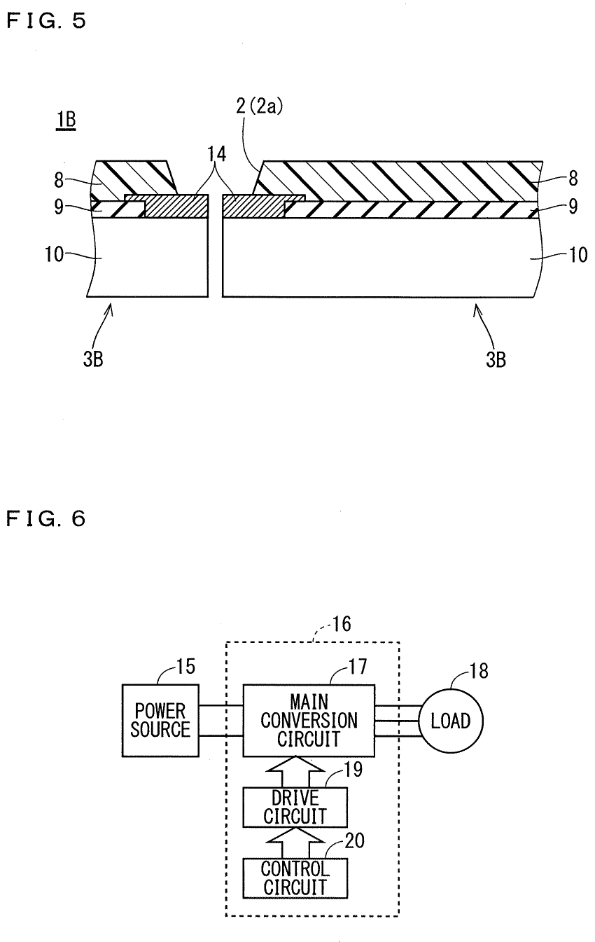

Next, a semiconductor wafer 1B according to the fourth embodiment will be described. FIG. 5 is a cross-sectional view of corners of semiconductor elements 3B to be formed by dicing in the semiconductor wafer 1B according to the fourth embodiment. Note that, in the fourth embodiment, the same components as those described in the first to third embodiments are denoted by the same reference signs, and description thereof is omitted.

As illustrated in FIG. 5, in the fourth embodiment, the AlSi film 14 is formed to be thicker than the interlayer insulating film 9, and is disposed from the outer peripheral surface of an end of the interlayer insulating film 9 over an end of the semiconductor substrate 10 to be formed by the dicing in each of the semiconductor elements 3B. The AlSi film 14 is disposed so as to cover the entire outer peripheral surface of the end of the interlayer insulating film 9 and a peripheral upper surface portion thereof, and functions as a buffer against a crack extending from a corner of the semiconductor element 3A.

When the AlSi film 14 is not disposed between the semiconductor substrate 10 and the surface protective film 8, external stress is applied to a contact point between the semiconductor substrate 10 and the surface protective film 8. In the fourth embodiment, however, the AlSi film 14 is disposed from the end of the interlayer insulating film 9 to the end of the semiconductor substrate 10 to be formed by the dicing in each of the semiconductor elements 3B. That is, since the AlSi film 14 is disposed from the end of the interlayer insulating film 9 to an end of the semiconductor element 3B, external stress is applied to a contact point between an end of the surface protective film 8, laminated so as to cover the interlayer insulating film 9, and the AlSi film 14 disposed from the end of the interlayer insulating film 9 to an end of the semiconductor element 3A. Since a linear expansion coefficient of the AlSi film 14 is larger than that of the semiconductor substrate 10, the external stress applied to the contact point is easily mitigated.

As described above, in the semiconductor wafer 1B according to the fourth embodiment, when the external stress due to thermal shrinkage stress is applied to the corner of the semiconductor element 3, the effect of suppressing the crack from extending to the lower side of the interlayer insulating film 9 can be further improved as compared with the case of the third embodiment.

### Fifth Embodiment

In the present embodiment, the semiconductor devices according to the above-described the first to fourth embodiments are applied to a power conversion apparatus. The application of the semiconductor devices according to the first to fourth embodiments is not limited to a specific power conversion apparatus, and a case where the semiconductor devices according to the first to fourth embodiments are applied to a three-phase inverter will be described below as a fifth embodiment.

FIG. 6 is a block diagram illustrating a configuration of a power conversion system to which a power conversion apparatus 16 according to the fifth embodiment is applied.

The power conversion system illustrated in FIG. 6 includes a power source 15, a power conversion apparatus 16, and a load 18. The power source 15 is a DC power source, and supplies DC power to the power conversion apparatus 16. The power source 15 can include various components, and for example, can include a DC system, a solar cell, and a storage battery, or may include a rectifier circuit and an AC/DC converter connected to an AC system. In addition, the power source 15 may include a DC/DC converter that converts DC power output from the DC system into predetermined power.

The power conversion apparatus 16 is a three-phase inverter connected between the power source 15 and the load 18, converts DC power supplied from the power source 15 into AC power, and supplies the AC power to the load 18. As illustrated in FIG. 6, the power conversion apparatus 16 includes a main conversion circuit 17 that converts DC power into AC power and outputs the AC power, a drive circuit 19 that outputs a drive signal for driving each of switching elements of the main conversion circuit 17, and a control circuit 20 that outputs a control signal for controlling the drive circuit 19 to the drive circuit 19.

The load 18 is a three-phase electric motor driven by the AC power supplied from the power conversion apparatus 16. Note that the load 18 is not limited to a specific application, but is an electric motor mounted on various types of electric equipment, and is used as, for example, an electric motor for a hybrid vehicle, an electric vehicle, a railway vehicle, an elevator, or an air conditioner.

Hereinafter, details of the power conversion apparatus 16 will be described. The main conversion circuit 17 includes the switching elements (not illustrated) and freewheeling diodes (not illustrated), converts DC power supplied from the power source 15 into AC power by switching the switching elements, and supplies the AC power to the load 18. Although there are various specific circuit configurations of the main conversion circuit 17, the main conversion circuit 17 according to the present embodiment is a two-level three-phase full bridge circuit, and can include six switching elements and six freewheeling diodes antiparallel to the respective switching elements. The semiconductor device according to any of the above-described the first to fourth embodiments is applied to at least one of the respective switching elements and the respective freewheeling diodes of the main conversion circuit 17. The six switching elements are connected in series two by two to form upper and lower arms, and each pair of the upper and lower arms constitutes each phase (U phase, V phase, W phase) of the full bridge circuit. Then, output terminals of each pair of the upper and lower arms, that is, three output terminals of the main conversion circuit 17 are connected to the load 18.

The drive circuit 19 generates a drive signal for driving each of the switching elements of the main conversion circuit 17, and supplies the drive signal to a control electrode of the switching element of the main conversion circuit 17. Specifically, to the control electrode of each of the switching elements, a drive signal for turning on the switching element and a drive signal for turning off the switching element are output in accordance with the control signal from the control circuit 20 to be described later. The drive signal is a voltage signal (ON signal) equal to or higher than a threshold voltage of the switching element in the case of maintaining the switching element in the ON state, and the drive signal is a voltage signal (OFF signal) equal to or lower than the threshold voltage of the switching element in the case of maintaining the switching element in the OFF state.

The control circuit 20 controls the switching elements of the main conversion circuit 17 such that desired power is supplied to the load 18. Specifically, a time (ON time) during which each of the switching elements of the main conversion circuit 17 is to be turned on is calculated based on the power to be supplied to the load 18. For example, the main conversion circuit 17 can be controlled by PWM control that modulates the ON time of the switching element in accordance with a voltage to be output. Then, a control command (control signal) is output to the drive circuit 19 such that the ON signal and the OFF signal are output to the switching element to be turned on and the switching element to be turned off, respectively, at each time point. The drive circuit 19 outputs the ON signal or the OFF signal as the drive signal to the control electrode of each of the switching elements in accordance with the control signal.

In the power conversion apparatus according to the present embodiment, the semiconductor devices according to the first to fourth embodiments are applied as the switching elements of the main conversion circuit 17, so that the durability can be improved.

Although the example in which the semiconductor devices according to the first to fourth embodiments are applied to the two-level three-phase inverter has been described in the present embodiment, the application of the semiconductor devices according to the first to fourth embodiments is not limited thereto, and the application to various power conversion apparatuses is possible. Although the two-level power conversion apparatus is assumed in the present embodiment, a three-level or multi-level power conversion apparatus may be assumed. In a case where power is supplied to a single-phase load, the semiconductor devices according to the first to fourth embodiments may be applied to a single-phase inverter. In addition, when power is supplied to a DC load or the like, the semiconductor devices according to the first to fourth embodiments can also be applied to a DC/DC converter or an AC/DC converter.

In addition, a power conversion apparatus to which the semiconductor devices according to the first to fourth embodiments are applied is not limited to the above-described case where the load is the electric motor, but can also be used as, for example, a power supply apparatus of an electric discharge machine, a laser processing machine, an induction heating cooker, or a wireless power supply system, and further, can also be used as a power conditioner for a photovoltaic power generation system or a power storage system.

### Sixth Embodiment

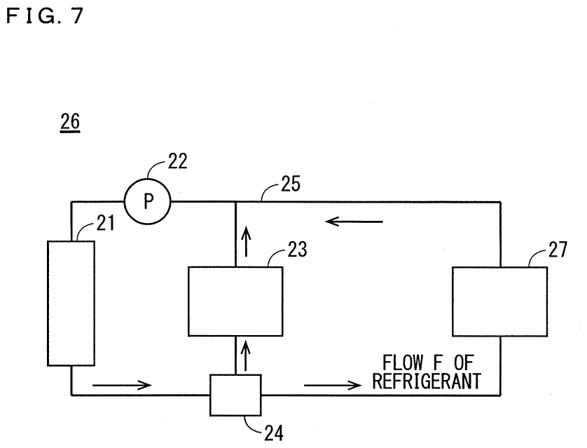

Next, a cooling system 26 according to a sixth embodiment will be described. FIG. 7 is a block diagram illustrating a configuration of the cooling system 26 according to the sixth embodiment.

For example, a power module (semiconductor device) of a power conversion apparatus mounted on a vehicle has a wider range of operating temperatures (for example, in the range of −40° C. or more and 150° C. or less) than a power module used indoors, and is used in a severe heat cycle environment.

In addition, in a low temperature environment, torque is applied to a motor at the time of starting, so that the temperature of the entire drive equipment rapidly rises. For example, in a case where snow accumulates in winter, high torque is required, and thus a higher load is applied to the drive equipment. For this reason, there is a problem that peeling between a sealing resin and a semiconductor element in the power module occurs so that dielectric breakdown of the semiconductor element occurs. The sixth embodiment has been made to solve such a problem, and will be described in detail below.

As illustrated in FIG. 7, the cooling system 26 includes a radiator 21, a pump 22, a battery cooling apparatus 23, a flow rate adjustment apparatus 24, a refrigerant flow path 25, and a PCU cooling apparatus 27.

In the cooling system 26, the apparatuses that cool a PCU (not illustrated) and a battery (not illustrated), respectively, are connected in parallel to the radiator (heat exchanger) 21 via the refrigerant flow path 25. As the pump 22 operates, a refrigerant flowing through the refrigerant flow path 25 flows in the illustrated direction of F. The flow rate adjustment apparatus 24 may be provided at a branch point where the refrigerant having passed through the radiator 21 branches into the battery cooling apparatus 23 and the PCU. Note that the battery cooling apparatus 23 and the PCU cooling apparatus 27 may be connected in series to the radiator 21.

As a result, a crack between the sealing resin (not illustrated) in the semiconductor device and the semiconductor element 3 (see FIG. 1) can be suppressed, so that a cooling load of the PCU cooling apparatus 27 is reduced as compared with the prior art, and the cooling capacity can be distributed to the battery. Since the battery cooling performance is improved, a cruising distance of the vehicle can be further extended as compared with the prior art. Further, a size of the PCU cooling apparatus 27 for cooling the PCU including the semiconductor device can be reduced. Therefore, the space in the vehicle can be effectively used.

Although the present disclosure has been described in detail, the above description is illustrative and not restrictive in all aspects. It is understood that numerous modifications not illustrated can be assumed.

Note that each of the embodiments can be freely combined, and each of the embodiments can be appropriately modified or omitted.

### EXPLANATION OF REFERENCE SIGNS

1 semiconductor wafer, 2a opening, 3, 3A, 3B semiconductor element, 8 surface protective film, 9 interlayer insulating film, 10 semiconductor substrate, 14 AlSi film, 16 power conversion apparatus, 17 main conversion circuit, 19 drive circuit, 20 control circuit, 21 radiator, 23 battery cooling apparatus, 25 refrigerant flow path, 26 cooling system, 27 PCU cooling apparatus.

1. A semiconductor wafer comprising a semiconductor substrate in which an interlayer insulating film and a surface protective film covering the interlayer insulating film are laminated on an upper surface,
wherein a plurality of semiconductor elements to be divided into small pieces by dicing along an opening formed in the surface protective film are formed on the semiconductor substrate,
an end of the interlayer insulating film is retracted more than an end of the surface protective film with respect to an end of the semiconductor substrate to be formed by the dicing, and
a shape of the end of the interlayer insulating film is set in such a manner that, in each of the semiconductor elements after the dicing, a distance Lx from a corner of the semiconductor substrate to be formed by the dicing to the end of the interlayer insulating film and a thickness d of the semiconductor substrate satisfy
$$Lx > 10 \times d - 717 μ m .$$

2. The semiconductor wafer according to claim 1, wherein
the interlayer insulating film at a corner of each of the semiconductor elements is formed in a curved shape in a top view, and
the shape of the end of the interlayer insulating film is set in such a manner that a width W of a dicing line, a kerf width C that is a width of the dicing line removed by the dicing, a width L from the end of the surface protective film to the end of the interlayer insulating film in each of the semiconductor elements, a curvature R of the interlayer insulating film at the corner of the semiconductor element, and the distance Lx satisfy
$$Lx = \sqrt{2} > < ( 〈 ( W - C ) / 2 + L ) + ( \sqrt{2} - 1 ) \times R .$$

3. The semiconductor wafer according to claim 1, wherein an AlSi film is disposed on an outer peripheral surface of the end of the interlayer insulating film in such a manner as to cover the end of the interlayer insulating film in each of the semiconductor elements.

4. The semiconductor wafer according to claim 3, wherein the AlSi film is formed to be thicker than the interlayer insulating film, and is disposed from the outer peripheral surface of the end of the interlayer insulating film over the end of the semiconductor substrate to be formed by the dicing in each of the semiconductor elements.

5. A semiconductor device comprising the semiconductor element obtained from the semiconductor wafer according to claim 1.

6. A semiconductor device comprising
a semiconductor element including a semiconductor substrate in which an interlayer insulating film and a surface protective film covering the interlayer insulating film are laminated on an upper surface,
wherein an end of the interlayer insulating film is retracted more than an end of the surface protective film with respect to an end of the semiconductor substrate which is an end of the semiconductor element, and
a shape of the end of the interlayer insulating film is set in such a manner that, in the semiconductor element, a distance Lx from a corner of the semiconductor substrate to the end of the interlayer insulating film and a thickness d of the semiconductor substrate satisfy
$$Lx > 10 \times d - 717 μ m .$$

7. The semiconductor device according to claim 6, wherein an AlSi film is disposed on an outer peripheral surface of the end of the interlayer insulating film in such a manner as to cover the end of the interlayer insulating film in the semiconductor element.

8. The semiconductor device according to claim 7, wherein the AlSi film is formed to be thicker than the interlayer insulating film, and is disposed from the outer peripheral surface of the end of the interlayer insulating film over the end of the semiconductor substrate in the semiconductor element.

9. A power conversion apparatus comprising:
a main conversion circuit that includes the semiconductor device according to claim 5 and converts input power and outputs the converted power;
a drive circuit that outputs a drive signal for driving the semiconductor device to the semiconductor device; and
a control circuit that outputs a control signal for controlling the drive circuit to the drive circuit.

10. A cooling system comprising:
a PCU including the semiconductor device according to claim 5;
a radiator that cools a refrigerant;
a battery that supplies power to the PCU;
a battery cooling apparatus that cools the battery using the refrigerant;
a PCU cooling apparatus that cools the PCU using the refrigerant; and
a refrigerant flow path through which the refrigerant flows.
